(19) United States
(12) Patent Application Publication
(10) Pub. No.: US 2026/0040867 A1
(43) Pub. Date: Feb. 5, 2026

(54) MATERIALS FOR PREVENTING ELECTROSTATIC DISCHARGE

(71) Applicant: Taiwan Semiconductor Manufacturing Co., Ltd., Hsinchu (TW)

(72) Inventors: Yuan-Chih LO, Hsinchu (TW); Cheng-Han WU, Hsinchu (TW); Ching-Yu CHANG, Hsinchu (TW)

(21) Appl. No.: 18/793,522

(22) Filed: Aug. 2, 2024

(51) Int. Cl. H01L 21/67; H01B 1/12; H01B 3/30

(52) U.S. Cl. CPC H01L 21/67126; H01B 1/128; H01B 3/307; H01L 21/67023

(57) ABSTRACT

An electrostatic discharge (ESD) mitigating article for storing a semiconductor device or for transporting a process fluid during semiconductor manufacturing is provided. The article includes a conductive polymer that comprises conjugated segments of arylene or heteroaryl groups connected to each other via an optional vinylene group, ethynylene group or a divalent linker comprising a carbon, nitrogen, oxygen, sulfur, selenium, or silicon atom in the polymer backbone.

### BACKGROUND

Electrostatic Discharge (ESD) is a natural phenomenon arising from static electricity. It occurs when two objects, each bearing positive and negative charges respectively, come into contact, allowing an electric current passing through the interface between these two objects. When ESD occurs, the electric current generates locally high energy density, resulting in sparks and high temperatures. The semiconductor industry is highly sensitive to ESD events, as they can cause malfunctions in electronic devices due to friction between electronic devices and plastic packaging. Additionally, sparks from ESD can ignite flammable gases, vapors, or fluid chemicals used in semiconductor manufacturing, potentially causing explosions. Consequently, ESD detrimentally impacts production yield, manufacturing cost, product quality, product reliability, and profitability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates exemplary articles comprising the conductive polymers of the present disclosure including ESD tubing (A) for packaging sensitive electronic devices, pipes (B) for transporting process fluids and filter membranes (C) for removing contaminants from process fluids.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Electrostatic discharge (ESD) poses a longstanding and significant challenge within the semiconductor industry, often resulting in unforeseen damage to integrated circuits (ICs). Protecting semiconductor devices from ESD is necessary to ensure the durability and reliability of the devices. ESD events involve the sudden release of electrostatic charge, leading to the generation of high electric fields and currents within an IC. The consequences of such ESD events can be detrimental, including the “blowing out” of gate dielectrics in transistors or the “melting” an active regions of the devices. These damages can render semiconductor devices less operable or entirely inoperable, adversely affecting production yields, manufacturing costs, product quality, reliability, and overall profitability.

The semiconductor IC industry has experienced exponential growth. Technological advances in IC materials and design have produced generations of ICs where each generation has smaller and more complex circuits than the previous generation. This increasing integration of functions, coupled with the reduction of chip floor space, has rendered the ICs more susceptible to damage caused by ESD. ICs contain various circuit elements, including conductive semiconductor regions, metal regions, insulators, and signal paths for electric signals, all intricately arranged within very small regions to form the essential circuit component such as transistors, capacitors, and resistors. For instances, complementary metal-oxide semiconductor (CMOS) technology employs field-effect transistors comprising highly doped source/drain semiconductor regions separated by an undoped or weakly doped channel region. The conductivity of the channel region is regulated by a gate electrode separated from the channel region by an insulation layer. As transistor dimensions continue to shrink to meet the demands of advancing technology, the thickness of the insulation layer also decreases to maintain precise control of the channel region, even at smaller dimensions.

The damage to electronic devices caused by ESD can take place at any stage, spanning from manufacturing to transportation and eventual use. To safeguard semiconductor devices during manufacturing ensure their safe delivery to customers, appropriate packaging is needed to prevent ESD during the storage, handling, and distribution.

During semiconductor device manufacturing, various types of fluids are used for processing semiconductor wafers and forming ICs on the wafers. These fluids are delivered from supply vessels to wafer processing equipment via a fluid delivery system. ESD is an important technical issue for fluid delivery systems in the semiconductor industry. Frictional contact between fluids and surfaces of various operational components (e.g. tubing or piping, valves, fittings, filters, etc.) in the fluid delivery system can result in the generation and buildup of static electrical charges. The extent of charge generation depends on various factors including the nature of the components and the fluid, fluid velocity, fluid viscosity, electrical conductivity of the fluid, pathways to ground, turbulence and shear in fluids, presence of air in the fluid, and surface area.

As the fluid flows through the system, the charge can be carried downstream in a phenomenon called streaming charge, where charges may build up beyond where the charges are originated. Sufficient charge accumulation can cause ESD at the tubing or pipe walls, surfaces of filter membranes, or even onto wafer substrates at various process steps. Such ESD can result in damage or destruction of the wafer. For instance, ESD can lead to the destruction of circuits on the wafer and premature activation of photoresists before regular exposure. Moreover, the accumulation of electrostatic charge within the fluid delivery system can discharge into the surrounding environment, potentially causing damage to the components within the fluid delivery system such as tubing or piping, fittings, components, containers, and filters. The damage may result in leaks or spills of fluid within the system, which leads to a decrease in performance of the components. In more severe scenarios, ESD may even pose a risk of fire or explosion, particularly when flammable, toxic, or corrosive fluids are utilized in the compromised fluid delivery system.

Semiconductor processes like photolithography, chemical mechanical polishing (CMP), wet etching, and clean have become more susceptible to metal contaminants at advanced process nodes. As a result, metals extracted from the fluid delivery systems can cause critical defects on wafers, negatively impacting process yields. To mitigate this issue, fabs have transitioned many of their stainless steel fluid delivery systems, traditionally used for transporting flammable solvents, to polymer systems, such as polyethylene (PE), high density polyethylene (HDPE), and perfluoroalkane (PFA). This shift to polymers has successfully reduced the presence of extracted metals in the process fluids.

However, the increased use of polymers in the fluid delivery systems raises new concerns regarding ESD. Process fluids used in the semiconductor industry typically have low conductivity, allowing them to generate and retain electric charge. When these process fluids are transported in the fluoropolymer systems, there is a significantly higher risk of static charge generation, accumulation, and discharge due to the nonconductive nature of the polymer materials and the low conductivity properties of the process fluids. ESD events generated in fluoropolymer systems transferring flammable process fluids can create leak paths through the tubing and potentially ignite the surrounding flammable process fluid-rich environment.

A common and effective approach to prevent ESD involves the use of conductive materials as packaging media for storing and transporting electronic devices or as pipelines or filter membranes in the fluid delivery system for transporting process fluids. Such antistatic conductive materials are typically composed of conductive additives, such as metal particles, graphite, or surfactant like polyethoxylated tallow amine, which are incorporated into polymer matrices or coated onto polymer substrates. This helps to prevent electrostatic accumulation by passivating or attracting moisture from the atmosphere.

However, these conductive additives may leach from the package media, causing contamination of the electronic devices. The conductive additives leaching from the pipelines and filter membranes of the fluid delivery system can result in decreased chemical purity, which is detrimental to the semiconductor manufacturing processes. The presence of these leached additives can adversely affect the electronic devices manufactured with such chemicals, rendering the devices deficient or even useless for their intended use.

Hence, there is a continuing demand for high-purity conductive materials for use in packaging media and components of the fluid delivery system such as pipelines and filter membranes, which can eliminate material contamination through device manufacturing, storage, and transport operations.

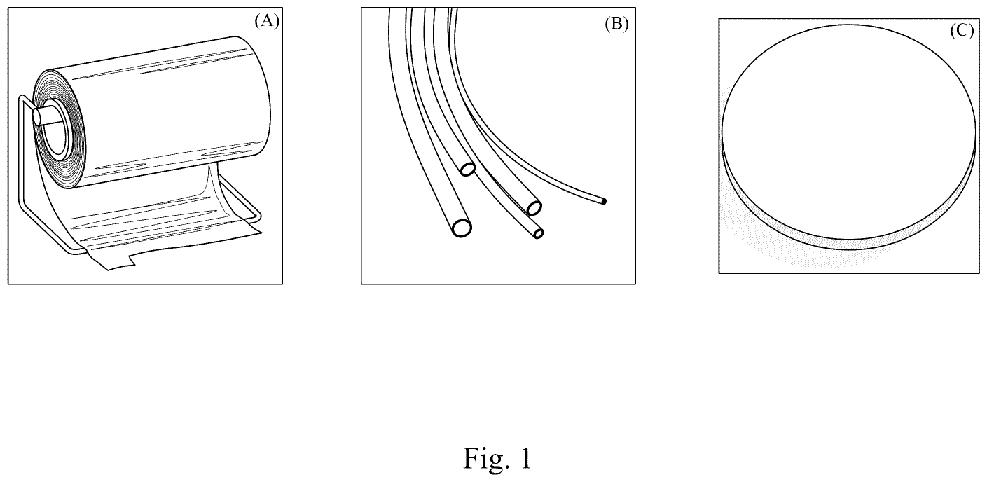

Embodiments of the present disclosure provided herein include using conductive polymers for prevention or mitigation of ESD. The conductive polymers of the present disclosure can be utilized in the construction of packaging media for transporting and storing electronic devices, or in the construction of components of fluid delivery systems including pipelines and filter membranes for delivering process fluids for semiconductor manufacturing. Exemplary articles comprising these conductive polymers such as ESD tubing (A) for packaging sensitive electronic devices, pipes (B) for transporting process fluids and filter membranes (C) for removing contaminants from process fluids are provided in FIG. 1. Due to the conductive nature of these polymers, there is no need for additional conductive additives to render the polymer conductive so as to prevent ESD. As a result, the conductive polymers of the present disclosure can ensure non-leaching and high purity of packaging media, pipelines and filter membranes, as they are free of additives. The utilization of conductive polymer of the present disclosure helps to improve production yield, manufacturing cost, product quality, product reliability, and profitability.

In one aspect, an article comprising a conductive polymer is provided. In some embodiments, an entirety of the article is made of the conductive polymer. In some embodiments, the conductive polymer is formed as a coating layer on a surface of a body of the article. In some embodiments, the body of the article is made of an electrically insulating polymer. In some embodiments, the body polymer may have good chemical resistance properties such as anti-acid or anti-base properties, which may be retained to high temperature. Examples of body polymers include, but are not limited to, polyesters, polycarbonates, polyamides, polyimides, polyurethanes, polyolefins, polystyrenes, polyketones, polyureas, polyvinyl resins, polyacrylates, polymethylacrylates, and fluoropolymers. In some embodiments, the body polymer is a fluoropolymer. Examples of fluoropolymers include, but are not limited to, perfluoroalkoxy alkane polymer (PFA), ethylene tetrafluoroethylene polymer (ETFE), ethylene tetrafluoroethylene and hexafluoropropylene polymer (EFEP), fluorinated ethylene propylene polymer (FEP), tetrafluoroethylene polymer (PTFE), polychlorotrifluoroethylene (PCTFE), or other suitable polymeric materials. In some embodiments, the fluoropolymer is perfluoroalkoxy alkane polymer (PFA). In some embodiments, the body polymer is a polyethylene (PE) or high-density polyethylene (HDPE).

The conductive polymer is a conjugated polymer comprising conjugated segments of arylene or heteroarylene groups connected to each other via an optional vinylene group, ethynylene group, or a divalent linker comprising a carbon, nitrogen, oxygen, sulfur, selenium, or silicon atom in the polymer backbone. In some embodiments, the conductive polymer is a homopolymer containing single monomeric repeating units. In some embodiments, the conductive polymer is a copolymer containing two different monomeric repeating units.

In some embodiments, the conductive polymer may have a number-average molecular (Mn) in the range of 500 Daltons (Da) to 500 kDa, such as from 1 kDa to 100 kDa, from 2 kDa to 100 kDa, from 10 kDa to 100 kDa, or from 50 kDa to 100 kDa. The conductive polymer may exhibit a glass transition temperature (Tg) greater than about 50° C., greater than about 60° C., greater than about 70° C., greater than about 80° C., greater than about 90° C., or greater than about 100° C. In some embodiments, the conductive polymer may exhibit Tg from about 50° C. to about 150° C. or from about 60° C. to about 100° C.

In some embodiments, the present disclosure provides a conductive polymer having the following structure (I):

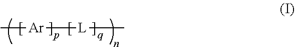

wherein:
Ar is, at each occurrence, an optionally substituted arylene or heteroarylene group;
L is, at each occurrence, a direct bond, an optionally substituted vinylene group, an ethynylene group or a divalent linker comprising at least one of a carbon, nitrogen, oxygen, sulfur, selenium or silicon atom in the polymer backbone;
p and q are each independently 0 or 1, provided at least one of p and q is 1; and
n is an integer from 1 to 100,000.

In compound of structure (I), the number of carbon atoms of the arylene group represented by Ar is, not including the number of carbon atoms of a substituent, from 6 to 30 or from 6 to 18. Examples of the arylene group include, but are not limited to, a phenylene group (for example, 1,2-phenylene, 1,3-phenylene or 1,4-phenylene), a naphthalenediyl group (for example, 1,4-naphthalenediyl, 1,5-naphthalenediyl, 2,6-naphthalenediyl and 2,7-naphthalenediyl), an anthracenediyl group (for example, 2,6-anthracenediyl and 9,10-anthracenediyl), phenanthrenediyl (for example, 2,7-phenanthrenediyl), a dihydrophenanthrenediyl group (for example, 9,10-dihydrophenanthrene-2,7-diyl), a naphthacenediyl group (for example, 5,12-naphthacenediyl), a fluorenediyl group (for example, 2,7-fluorenediyl and 3,6-fluorenediyl), a spirofluorenediyl group (for example, 9,9′-spirofluorene-2,7-diyl, 9,9′-spirofluorene-3,6-diyl and 9,9′-spirofluorene-2,2′-diyl), and a perylenediyl group (for example, 3,8-perylenediyl). In some embodiments, the arylene group may be substituted with one or more substitutes.

The number of carbon atoms of heteroarylene group represented by Ar is, not including the number of carbon atoms of a substitute, from 5 to 30 or from 5 to 18. Examples of heteroarylene group include, but are not limited to, a 2,5-thiophenediyl group, a 2,5-pyrrolediyl group, a 2,5-furandiyl group, a 2,5-pyridinediyl group, a 2,6-pyridinediyl group, a 2,6-quinolinediyl group, a 1,4-isoquinolinediyl group, a 1,5-isoquinolinediyl group, a 5,8-quinoxalinediyl group, a 2,7-carbazolediyl group, a 3,6-carbazolediyl group, a 3,7-phenoxazinediyl group, a 3,7-phenothiazinediyl group, a 2,8-phenothiazinediyl group, a 4,6-phenothiazinediyl group, a 2,1,3-benzothiadiazole-4,7-diyl group, a 2,7-dibenzofurandiyl group, and a 2,7-dibenzothiophenediyl group. In some embodiments, the heteroarylene group may be substituted with one or more substitutes.

In some embodiments, Ar is phenylene, fluorene, benzofluorene, phenanthrene, naphthalene or anthracene group.

In some embodiments, at least one occurrence of Ar is unsubstituted. In some embodiments, each occurrence of Ar is unsubstituted.

In some embodiments, at least one occurrence of Ar is substituted. In some embodiments, each occurrence of Ar is substituted.

The group represented by Ar or vinylene may have one or more substituents. In some embodiments, the one or more substituents independently include an unsubstituted alkyl group, an substituted alkyl group (for example, fluoroalkyl, perfluoroalkyl, alkyl-NO₂, alkyl-NO₃⁻, or alkyl-SO₃⁻), an alkoxy group, a halogen atom (for example, F, Cl, Br, or I), a hydroxyl group (—OH), an amino group, or an ester group.

In some embodiments, the divalent L linker may be selected from the group consisting of —C(R^{a})(R^{b})—, —N(R^{a})—, —O—, —S—, —Se— and Si(R^{a})(R^{b})—, with R^{a} and R^{b} each independently H, an alkyl group, or an alkoxy group.

The alkyl group represented by R^{a} and R^{b} may be any of linear, branched or cyclic, and the number of carbon atoms of the linear alkyl group is, not including the number of carbon atoms of a substituent, 1 to 20. The number of carbon atoms of the branched or cyclic alkyl groups is, not including the number of carbon atoms of a substituent, 3 to 20. Examples of the alkyl group include, but are not limited to, a methyl group, an ethyl group, a n-propyl group, an isopropyl group, a n-butyl group, an isobutyl group, a tert-butyl group, a n-pentyl group, an isoamyl group, a n-hexyl group, a cyclohexyl group, a n-heptyl group, a cyclohexylmethyl group, a n-octyl group, a 2-ethylhexyl group, a n-decyl group, a 3,7-dimethyloctyl group, a 2-ethyloctyl group, and a 2-n-hexyl-decyl group. In some embodiments, the alkyl group may be substituted with one or more substitutes. In some embodiments, R^{a} and R^{b} are independently C1-C12 alkyl or C1-C10 alkyl.

The alkoxy group represented by R^{a} and R^{b} may be any of linear or branched. The number of carbon atoms of the linear alkoxy group is, not including the number of carbon atoms of a substituent, 1 to 20. The number of carbon atoms of the branched or cyclic alkoxy groups is, not including the number of carbon atoms of a substituent, 3 to 20. Examples of the alkoxy group includes, but are not limited to, a methoxy group, an ethoxy group, a n-propyloxy group, an isopropyloxy group, a n-butyloxy group, an isobutyloxy group, a tert-butyloxy group, a n-pentyloxy group, a n-hexyloxy group, a cyclohexyloxy group, a n-heptyloxy group, a n-octyloxy group, a 2-ethylhexyloxy group, a n-nonyloxy group, a n-decyloxy group, a 3,7-dimethyloctyloxy group, and a lauryloxy group. In some embodiments, the alkoxy group may be substituted with one or more substitutes. In some embodiments, R^{a} and R^{b} are independently C1-C12 alkoxy or C1-C10 alkoxy.

In some embodiments, n is 5 or more, such as 10 or more, 30 or more, 100 or more, 300 or more, 1000 or more, 3000 or more. In some embodiments, n is 5 to 80,000, 10 to 80,000, or 100 to 10,000.

In some embodiments, Ar is substituted phenylene, L is a direct bond, p is 1, and q is 0. For example, in some embodiments, the compound has the following structure (IA):

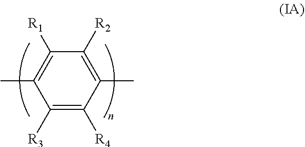

wherein:
R₁, R₂, R₃ and R₄ are, at each occurrence, independently H, F, Cl, Br, I, alkyl, alkoxy, COOH, N(R^{a})(R^{b}), COOR^{a} or epoxy, wherein the alkyl is unsubstituted or substituted with one or more substituents selected from the group consisting of —F, —Cl, —Br, —I, —OH, —NO₂, NO₃⁻ or —SO₃⁻; and
R^{a} and R^{b} are each independently H, alkyl or alkoxy.

In some embodiments, Ar is substituted naphthalenediyl, L is a direct bond, p is 1, and q is 0. For example, in some embodiments, the compound has the following structure (IB):

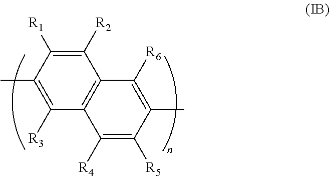

wherein:
R₁, R₂, R₃, R₄, R₅ and R₆ are, at each occurrence, independently, H, F, Cl, Br, I, alkyl, alkoxy, COOH, N(R^{a})(R^{b}), COOR^{a} or epoxy, wherein the alkyl is unsubstituted or substituted with one or more substituents selected from the group consisting of —F, —Cl, —Br, —I, —OH, —NO₂, NO₃⁻ or —SO₃⁻; and
R^{a} and R^{b} are each independently H, alkyl or alkoxy.

In some embodiments, Ar is substituted heteroarylene, L is a direct bond, p is 1, and q is 0. For example, in some embodiments, the compound has the following structure (IC):

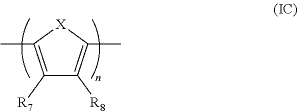

wherein:
X is —C(R^{a})(R^{b})—, —N(R^{a})—, —O—, —S—, —Se— or Si(R^{a})(R^{b})—;
R⁷ and R⁸ are, at each occurrence, independently, H, F, Cl, Br, I, C1-C12 alkyl, C1-C12 alkoxy, COOH, N(R^{a})(R^{b}), COOR^{a} or epoxy, wherein the C1-C12 alkyl is unsubstituted or substituted with one or more substituents selected from the group consisting of —F, —Cl, —Br, —I, —OH, —NO₂, NO₃⁻ or —SO₃⁻; and
R^{a} and R^{b} are each independently H, alkyl or alkoxy.

In some embodiments, L is substituted vinylene, p is 0, and q is 1. For example, in some embodiments, the compound has the following structure (ID):

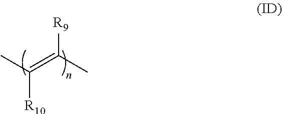

wherein:
R⁹ and R¹⁰ are, at each occurrence, independently, H, F, Cl, Br, I, alkyl, alkoxy, COOH, N(R^{a})(R^{b}), COOR^{a} or epoxy, wherein the alkyl is unsubstituted or substituted with one or more substituents selected from the group consisting of —F, —Cl, —Br, —I, —OH, —NO₂, NO₃⁻ or —SO₃⁻; and
R^{a} and R^{b} are each independently H, alkyl or alkoxy.

In some embodiments, Ar is substituted phenylene, L is vinylene, p is 1, and q is 1. For example, in some embodiments, the compound has the following structure (IE):

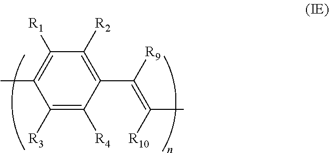

wherein:
R¹, R², R³, R⁴, R⁹ and R¹⁰ are, at each occurrence, independently, H, F, Cl, Br, I, alkyl, alkoxy, COOH, N(R^{a})(R^{b}), COOR^{a} or epoxy, wherein the C1-C12 alkyl is unsubstituted or substituted with one or more substituents selected from the group consisting of —F, —Cl, —Br, —I, —OH, —NO₂, NO₃⁻ or —SO₃⁻; and
R^{a} and R^{b} are each independently H, alkyl or alkoxy.

In some embodiments, Ar is substituted naphthalenediyl, L is vinylene, p is 1, and q is 1. For example, in some embodiments, the compound has the following structure (IF):

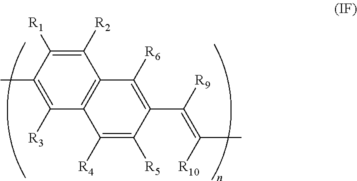

wherein:
R¹, R², R³, R⁴, R⁵, R⁶, R⁹ and R¹⁰ are, at each occurrence, independently, H, F, Cl, Br, I, alkyl, alkoxy, COOH, N(R^{a})(R^{b}), COOR^{a} or epoxy, wherein the C1-C12 alkyl is unsubstituted or substituted with one or more substituents selected from the group consisting of —F, —Cl, —Br, —I, —OH, —NO₂, NO₃⁻ or —SO₃⁻; and
R^{a} and R^{b} are each independently H, alkyl or alkoxy.

In some embodiments, Ar is substituted phenylene, L is a divalent linker, p is 1, and q is 1. For example, in some embodiments, the compound has the following structure (IG):

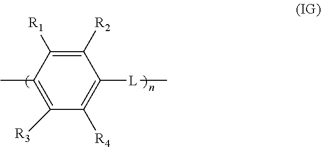

wherein:
R¹, R², R³ and R⁴ are, at each occurrence, independently, H, F, Cl, Br, I, alkyl, alkoxy, COOH, N(R^{a})(R^{b}), COOR^{a} or epoxy, wherein the C1-C12 alkyl is unsubstituted or substituted with one or more substituents selected from the group consisting of —F, —Cl, —Br, —I, —OH, —NO₂, NO₃⁻ or —SO₃⁻;
L is —C(R^{a})(R^{b})—, —N(R^{a})—, —O—, —S—, —Se— and Si(R^{a})(R^{b})—; and
R^{a} and R^{b} are each independently H, alkyl or alkoxy.

In compounds of structures (IA)-(IG), in some embodiments, the alkyl group represented by R¹, R², R³, R⁴, R^{a} and R^{b} are independently C1-C12 alkyl. In some embodiments, the alkoxy group represented by R¹, R², R³, R⁴, R^{a} and R^{b} are independently C1-C12 alkoxy.

In some embodiments, the conductive polymer of structure (I) has one of the following structures:

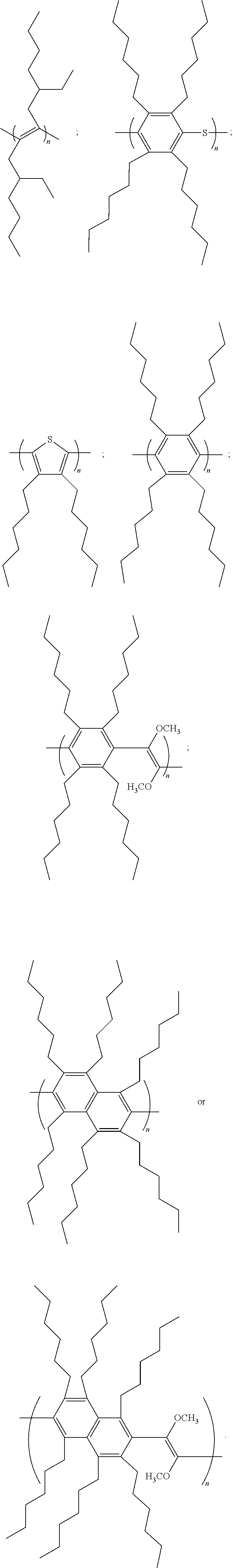

In some embodiments, the article comprises a base polymer and a conductive polymer of structure (I). The base polymer has an electrical conductivity less than the conductivity of the conductive polymer of structure (I). In some embodiments, the base polymer is an electrically insulating material. In some embodiments, the base polymer may have good chemical resistance properties such as anti-acid or anti-base properties, which may be retained to high temperature. Examples of the base polymer include, but are not limited to, polyesters, polycarbonates, polyamides, polyimides, polyurethanes, polyolefins, polystyrenes, polyketones, polyureas, polyvinyl resins, polyacrylates, polymethylacrylates, and fluoropolymers. In some embodiments, the base polymer is a fluoropolymer. Examples of the fluoropolymers include, but are not limited to, perfluoroalkoxy alkane polymer (PFA), ethylene tetrafluoroethylene polymer (ETFE), ethylene tetrafluoroethylene and hexafluoropropylene polymer (EFEP), fluorinated ethylene propylene polymer (FEP), tetrafluoroethylene polymer (PTFE), polychlorotrifluoroethylene (PCTFE), or other suitable polymeric materials. In some embodiments, the fluoropolymer is perfluoroalkoxy alkane polymer (PFA). In some embodiments, the base polymer is a polyethylene (PE) or high-density polyethylene (HDPE).

The content of the conductive polymer of structure (I) in the base polymer is controlled so that the article produced from the composite of the base polymer and the conductive polymer has a surface resistance in the static dissipate range of greater than 1×10⁴ Ω/sq, but less than 1×10¹¹ Ω/sq in order to control the discharge. If the surface resistance is too small, a charge can dissipate too quickly and electrically overstress the ICs within the packing medium. In some embodiments, the amount of the conductive polymer of structure (I) in the base polymer ranges from 5 wt % to 80 wt %, from 10 wt % to 80 wt %, from 20 wt % to 80 wt %, from 30 wt % to 80 wt %, from 40 wt % to 80 wt %, from 50 wt % to 80 wt %, from 60 wt % to 80 wt %. In some embodiments, the amount of the conductive polymer of structure (I) in the base polymer is about 75 wt %.

In some embodiments, the article serves as a packaging medium for protecting the semiconductor devices against ESD during their transportation within the fab during manufacturing or delivery to the customers. The article may take various forms. In some embodiments, the article may be a tray, tape, reel, tube, magazine, box, or bag. When the semiconductor devices are stored in the packing medium fabricated from the conductive polymers of the present disclosure and are transported from one place to another place, the ESD is mitigated due to the presence of the conductive polymer of the present disclosure.

In some embodiments, the article serves an ESD mitigation pipeline within a fluid delivery system for transporting process fluids during semiconductor device manufacturing processes.

In some embodiments, the article serves an ESD mitigation filter membrane within a fluid delivery system for filtering process fluids during semiconductor device manufacturing processes.

In some embodiments, the process fluid includes ultra-pure water, photoresist, developer, organic solvents, liquid nitrogen (N₂) or argon (Ar) gas. In some embodiments, the process fluid may be a solvent used for preparing photoresist compositions. Examples of solvents includes, but are not limited to, propylene glycol monomethyl ether acetate (PGMEA), propylene glycol monomethyl ether (PGME), 1-ethoxy-2-propanol (PGEE), 7-butyrolactone (GBL), cyclohexanone (CHN), ethyl lactate (EL), methanol, ethanol, propanol, n-butanol, acetone, dimethylformamide (DMF), isopropanol (IPA), tetrahydrofuran (THF), methyl isobutyl carbinol (MIBC), n-butyl acetate (nBA), and 2-heptanone (MAK). In some embodiments, the process fluid may be a developer used for forming resist patterns. Examples of developers include, but are not limited to, tetramethylammonium hydroxide (TMAH) and butyl acetate.

In some embodiments, the process fluid has an electric resistance greater than 1×10⁷ ohms (Ω). In some embodiments, the process fluid has an electric resistance greater than 2×10⁷ MΩ. When the process fluid flows through the pipelines and filter membranes fabricated from the conductive polymers of the present disclosure, the ESD is mitigated due to the presence of the conductive polymers of the present disclosure.

In one aspect, an electrostatic discharge (ESD) mitigating article for storing a semiconductor device is provided. The article includes a conductive polymer, the conductive polymer comprising conjugated segments of arylene or heteroaryl groups connected to each other via an optional vinylene group, ethynylene group or a divalent linker comprising a carbon, nitrogen, oxygen, sulfur, selenium, or silicon atom in the polymer backbone.

In another aspect, a fluid delivery system for transporting a process fluid during semiconductor manufacturing is provided. The fluid delivery system includes an electrostatic discharge (ESD) mitigating article comprising a conductive polymer having the following structure (I):

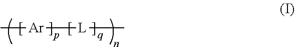

wherein: Ar is, at each occurrence, an optionally substituted arylene or heteroarylene group; L is, at each occurrence, a direct bond, an optionally substituted vinylene group, an ethynylene group or a divalent linker comprising at least one of a carbon, nitrogen, oxygen, sulfur, selenium or silicon atom in the polymer backbone; p and q are each independently 0 or 1, provided at least one of p and q is 1; and n is an integer from 1 to 100,000.

In still another aspect, an electrostatic discharge (ESD) mitigating article is provided. The ESD mitigating article includes a conductive polymer having the following structure (I):

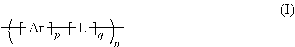

wherein: Ar is, at each occurrence, an optionally substituted arylene or heteroarylene group; L is, at each occurrence, a direct bond, an optionally substituted vinylene group, an ethynylene group or a divalent linker comprising at least one of a carbon, nitrogen, oxygen, sulfur, selenium or silicon atom in the polymer backbone; p and q are each independently 0 or 1, provided at least one of p and q is 1; and n is an integer from 1 to 100,000. The article is a packaging medium for storing a semiconductor device or a component of a fluid delivery system for transporting a process fluid during semiconductor manufacturing.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An electrostatic discharge (ESD) mitigating article for storing a semiconductor device, the article comprising a conductive polymer, the conductive polymer comprising conjugated segments of arylene or heteroaryl groups connected to each other via an optional vinylene group, ethynylene group or a divalent linker comprising a carbon, nitrogen, oxygen, sulfur, selenium, or silicon atom in the polymer backbone.

2. The article of claim 1, wherein an entirety of the article is made of the conductive polymer.

3. The article of claim 1, wherein the article comprises a coating layer on a surface of a body, wherein the coating layer is made of the conductive polymer and the body is made of an electrically insulating polymer.

4. The article of claim 3, wherein the electrically insulating polymer comprises polyethylene, high-density polyethylene or perfuoroalkoxy alkane polymer.

5. The article of claim 1, wherein the conductive polymer has the following structure (I): 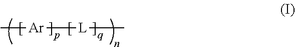
wherein:
Ar is, at each occurrence, an optionally substituted arylene or heteroarylene group;
L is, at each occurrence, a direct bond, an optionally substituted vinylene group, an ethynylene group or a divalent linker comprising at least one of a carbon, nitrogen, oxygen, sulfur, selenium or silicon atom in the polymer backbone;
p and q are each independently 0 or 1, provided at least one of p and q is 1; and
n is an integer from 1 to 100,000.

6. The article of claim 5, wherein at least one occurrence of Ar is a substituted phenylene, fluorenediyl, phenanthrenediyl, naphthalenediyl or anthracenediyl group.

7. The article of claim 6, wherein at least one occurrence of Ar is substituted with alkyl, fluoroalkyl, perfluoroalkyl, alkyl-NO₂, alkyl-NO₃⁻, or alkyl-SO₃⁻, alkoxy, halogen, hydroxyl, amino or ester.

8. The article of claim 5, wherein at least one occurrence of Ar is a substituted thiophenediyl, pyrrolediyl or carbazolediyl group.

9. The article of claim 5, wherein L is a divalent linker selected from the group consisting of —C(R^{a})(R^{b})—, —N(R^{a})—, —O—, —S—, —Se— and Si(R^{a})(R^{b})—, wherein R^{a} and R^{b} are each independently H, an alkyl group, or an alkoxy group.

10. The article of claim 5, wherein the conductive polymer has one of the following structures:

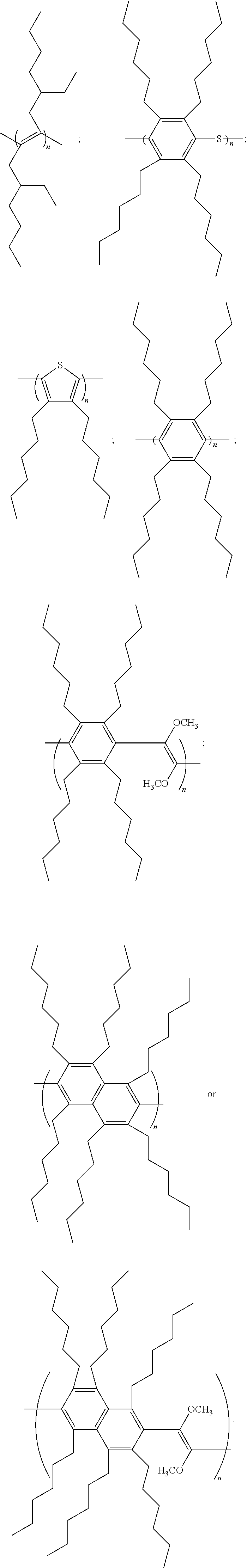

11. A fluid delivery system for transporting a process fluid during semiconductor manufacturing, comprising:
an electrostatic discharge (ESD) mitigating article comprising a conductive polymer having the following structure (I): 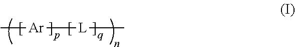
wherein:
Ar is, at each occurrence, an optionally substituted arylene or heteroarylene group;
L is, at each occurrence, a direct bond, an optionally substituted vinylene group, an ethynylene group or a divalent linker comprising at least one of a carbon, nitrogen, oxygen, sulfur, selenium or silicon atom in the polymer backbone;
p and q are each independently 0 or 1, provided at least one of p and q is 1; and
n is an integer from 1 to 100,000.

12. The fluid delivery system of claim 11, wherein p is 1 and q is 0, wherein the conductive polymer has the following structure (IA), (IB) or (IC): 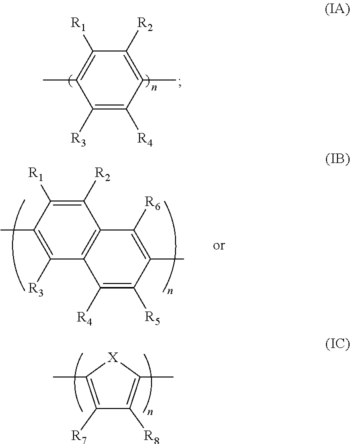
wherein:
R₁, R₂, R₃, R₄, R₅, R₆, R₇ and R₈ are, at each occurrence, independently, H, F, Cl, Br, I, alkyl, alkoxy, COOH, N(R^{a})(R^{b}), COOR^{a} or epoxy, wherein the alkyl is unsubstituted or substituted with one or more substituents selected from the group consisting of —F, —Cl, —Br, —I, —OH, —NO₂, NO₃⁻ or —SO₃⁻;
X is —C(R^{a})(R^{b})—, —N(R^{a})—, —O—, —S—, —Se— or Si(R^{a})(R^{b})—; and
R^{a} and R^{b} are each independently H, alkyl or alkoxy.

13. The fluid delivery system of claim 11, wherein p is 0 and q is 1, and wherein the conductive polymer has the following structure (ID): 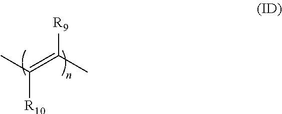
wherein:
R⁹ and R¹⁰ are, at each occurrence, independently, H, F, Cl, Br, I, alkyl, alkoxy, COOH, N(R^{a})(R^{b}), COOR^{a} or epoxy, wherein the alkyl is unsubstituted or substituted with one or more substituents selected from the group consisting of —F, —Cl, —Br, —I, —OH, —NO₂, NO₃⁻ or —SO₃⁻; and
R^{a} and R^{b} are each independently H, alkyl or alkoxy.

14. The fluid delivery system of claim 11, wherein p is 1 and q is 1, and wherein the conductive polymer has the following structure (IE), (IF) or (IG): 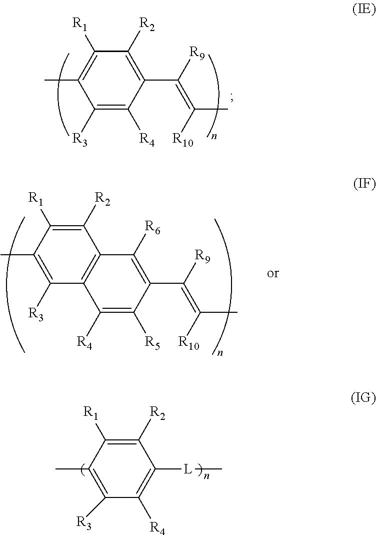
wherein:
R¹, R², R³, R⁴, R⁵, R⁶, R⁹ and R¹⁰ are, at each occurrence, independently, H, F, Cl, Br, I, alkyl, alkoxy, COOH, N(R^{a})(R^{b}), COOR^{a} or epoxy, wherein the alkyl is unsubstituted or substituted with one or more substituents selected from the group consisting of —F, —Cl, —Br, —I, —OH, —NO₂, NO₃⁻ or —SO₃⁻;
L is —C(R^{a})(R^{b})—, —N(R^{a})—, —O—, —S—, —Se— and Si(R^{a})(R^{b})—; and
R^{a} and R^{b} are each independently H, alkyl or alkoxy.

15. The fluid delivery system of claim 11, wherein the article is a pipeline or a filter membrane.

16. The fluid delivery system of claim 11, wherein the article further comprises a base polymer in combination with the conductive polymer.

17. The fluid delivery system of claim 16, wherein the base polymer comprises polyethylene, high-density polyethylene or perfuoroalkoxy alkane polymer.

18. An electrostatic discharge (ESD) mitigating article comprising a conductive polymer having the following structure (I): 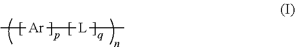
wherein:
Ar is, at each occurrence, an optionally substituted arylene or heteroarylene group;
L is, at each occurrence, a direct bond, an optionally substituted vinylene group, an ethynylene group or a divalent linker comprising at least one of a carbon, nitrogen, oxygen, sulfur, selenium or silicon atom in the polymer backbone;
p and q are each independently 0 or 1, provided at least one of p and q is 1; and
n is an integer from 1 to 100,000,
wherein the article is a packaging medium for storing a semiconductor device or a component of a fluid delivery system for transporting a process fluid during semiconductor manufacturing.

19. The article of claim 18, wherein the conductive polymer has the following structure
(IA), (IB), (IC), (ID), (IE), (IF) or (IG): 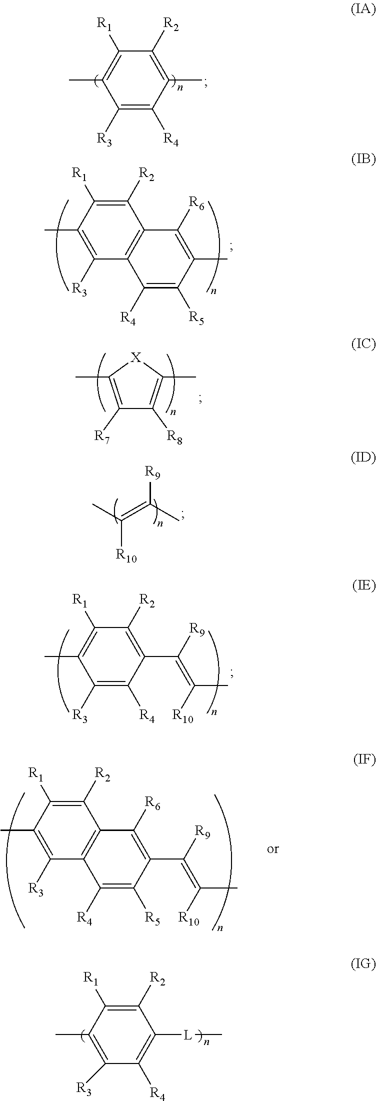
wherein:
R¹, R², R³, R⁴, R⁵, R⁶, R⁷, R⁸, R⁹ and R¹⁰ are, at each occurrence, independently, H, F, Cl, Br, I, alkyl, alkoxy, COOH, N(R^{a})(R^{b}), COOR^{a} or epoxy, wherein the alkyl is unsubstituted or substituted with one or more substituents selected from the group consisting of —F, —Cl, —Br, —I, —OH, —NO₂, NO₃⁻ or —SO₃⁻;
X is —C(R^{a})(R^{b})—, —N(R^{a})—, —O—, —S—, —Se—, or —Si(R^{a})(R^{b})—;
L is —C(R^{a})(R^{b})—, —N(R^{a})—, —O—, —S—, —Se— and Si(R^{a})(R^{b})—; and
R^{a} and R^{b} are each independently H, alkyl or alkoxy.

20. The article of claim 18, wherein the conductive polymer has one of the following structures: [chemical structure]
